(19) United States
(12) Patent Application Publication
(10) Pub. No.: US 2002/0080579 A1
(43) Pub. Date: Jun. 27, 2002

(54) Cooling unit for cooling a heat-generating component, and electronic apparatus having a cooling unit

(75) Inventor: Kazuya Shibasaki, Hamura-shi (JP)

Correspondence Address: Finnegan, Henderson, Farabow,, Garrett & Dunner, L.L.P., 1300 I Street, N.W., Washington, DC, 20005-3315, US

(73) Assignee: KABUSHIKI KAISHA TOSHIBA

(21) Appl. No.: 10/004,884

(22) Filed: Dec. 7, 2001

(30) Foreign Application Priority Data
Dec. 27, 2000 (JP) 2000-398100

(51) Int. Cl. H05K 7/20

(52) U.S. Cl. 361/688

(57) ABSTRACT

A cooling unit comprises a main body, a fan, and a plurality of heat-exchanging elements. The main body receives heat from a heat-generating component and has a cooling air passage. The fan applies cooling air into the cooling air passage. The heat-exchanging elements are exposed in the cooling air passage. Each element is removably secured to the main body and thermally connected to the main body.

### CROSS-REFERENCE TO RELATED APPLICATIONS

This application is based upon and claims the benefit of priority from the prior Japanese Patent Application No. 2000-398100 filed Dec. 27, 2000, the entire contents of which are incorporated herein by reference.

### BACKGROUND OF THE INVENTION

1. Field of the Invention

The present invention relates to a cooling unit for forcibly cooling a heat-generating component such as a semiconductor package, and an electronic apparatus incorporating the cooling unit.

2. Description of the Related Art

Portable computers comprise a microprocessor that processes multimedia data such as characters, sound and images. A microprocessor of this type consumes increasingly electric power as its operating speed increases and as it acquires increasingly functions. The amount of heat it generates while operating increases much, in proportion to the power it consumes. The efficiency of radiating heat from the microprocessor must therefore be enhanced to enable the portable computer to operate reliably.

To this end, conventional portable computers incorporate a cooling unit that forcibly cools a microprocessor. The cooling unit comprises a heat sink and an electric fan. The heat sink is thermally connected to the microprocessor. The electric fan applies cooling air to the heat sink.

The heat sink has a cooling air passage and a plurality of heat-radiating fins. Cooling air flows through the cooling air passage. The heat-radiating fins are exposed in the cooling air passage. The fins are forcibly cooled with the cooling air flowing through the cooling air passage. Hence, most of the heat conducted from the microprocessor to the heat sink is radiated by virtue of the heat exchange between the heat-radiating fins and the cooling air.

In the conventional cooling unit, the cooling air flowing through the cooling air passage is the main coolant takes heat from the microprocessor. The efficiency of cooling the microprocessor largely depends on the air-applying ability of the electric fan. In other words, the efficiency of cooling the microprocessor and the flow rate of cooling air are proportional to each other. The higher the flow rate, the greater the microprocessor-cooling efficiency. On the other hand, the higher the flow rate of cooling air, the high the rotation speed of the electric fan. A high rotation speed of the fan results in an increase of the noise the fan makes.

To enhance the efficiency of cooling the microprocessor, while controlling the noise of the electric fan, it is important to adjust the flow rate of cooling air and the number of heat-radiating fins and to design the fins in an appropriate shape.

The heat-radiating fins are formed integral with the main body of the conventional heat sink by means of casting. The fins exposed in the cooling air passage are provided in a fixed number and arranged at fixed positions. Neither the number of fins nor the positions of the fins can be changed in order to apply the cooling air in an appropriate rate. Consequently, it is impossible to radiate heat from the microprocessor at an optimal efficiency, while controlling the noise the fan makes.

To provide cooling units that vary in terms of the number of fins and positions thereof, many casting dies must be prepared. This would increase the manufacturing cost of the cooling units.

### BRIEF SUMMARY OF THE INVENTION

The present invention has been made in view of the foregoing. A first object of the invention is to provide a cooling unit that easily acquires a cooling efficiency appropriate for the heat a heat-generating component generates. A second object of the invention is to provide an electronic apparatus that has such a cooling unit.

To achieve the first object, a cooling unit according to a first aspect of the present invention comprises: a main body which is thermally connected to the heat-generating component and having a cooling air passage; a fan which applies cooling air into the cooling air passage; and a plurality of heat-exchanging elements exposed in the cooling air passage and being thermally conductive. Each of the heat-exchanging elements are removably secured to the main body and thermally connected to the main body.

To achieve the second object, an electronic apparatus according to a second aspect of this invention comprises: a housing containing a heat-generating component; and a cooling unit provided in the housing and configured to cool the heat-generating component. The cooling unit comprises a main body configured to receive heat from the heat-generating component, a cooling air passage provided in the main body and configured to receive cooling air, and a plurality of heat-exchanging elements exposed in the cooling air passage and being thermally conductive. Each of the heat-exchanging elements are removably secured to the main body and thermally connected to the main body.

The heat-exchanging elements, which contact the cooling air, are removably secured to the main body. The number of heat-exchanging elements used and the positions thereof can be changed freely in accordance with the flow rate of the cooling air and the flow-rate distribution thereof in the cooling air passage.

Hence, the degree at which the heat-exchanging elements hamper the flow of cooling air can be adjusted in accordance with the flow rate of the cooling air. This enables the cooling unit to acquire an optimal cooling ability that the unit should have in view of not only the flow rate of the cooling air in the passage, but also the amount of heat generated by the heat-generating component.

In order to attain the first object mentioned above, a cooling unit according a third aspect of the invention comprises: a main body which is thermally connected to a heat-generating component and having a cooling air passage; a fan which applies cooling air into the cooling air passage; and a plurality of heat-exchanging elements exposed in the cooling air passage and being thermally conductive. Each of the heat-exchanging elements includes a columnar part and a plurality of heat-radiating parts. The columnar part is removably secured to the main body and thermally connected to the main body. The heat-radiating parts project from a circumferential surface of the columnar part and are arranged at intervals in an axial direction of the columnar part. The heat-exchanging elements have such positional relation that each has its heat-radiating parts overlapping the heat-radiating parts of some other heat-exchanging elements.

As in the cooling units according to the first and second aspects of the invention, the number of heat-exchanging elements used and the positions thereof can be changed freely in accordance with the flow rate of the cooling air and the flow-rate distribution thereof in the cooling air passage. Further, various types of heat-exchanging elements may be prepared, each having a columnar part of different diameter and heat-radiating parts of a different shape. In this case, heat-exchanging element of one type selected in accordance with the rate at which the cooling air flows in the cooling air passage can be fastened to the main body.

In addition, any adjacent heat-exchanging elements do not interfere with one another in the cooling air passage. Many heat-exchanging elements can therefore be provided at high density, shortening the distance between them in the cooling air passage. This enhances the freedom of adjusting the degree at which the elements hamper the flow of cooling air, in accordance with the flow rate of the cooling air. Furthermore, this enables the cooling unit to acquire an optimal cooling ability that the unit should have in view of not only the flow rate of the cooling air in the passage, but also the amount of heat generated by the heat-generating component.

Additional objects and advantages of the invention will be set forth in the description that follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view of a portable computer according to a first embodiment of this invention;

FIG. 2 is a sectional view of the portable computer, illustrating the positional relation between the housing and the cooling unit provided in the housing;

FIG. 3 is a sectional view of the portable computer, taken along line F3-F3 shown in FIG. 2;

FIG. 4 is a perspective view, depicting the positional relation between the cooling air passage and the heat-exchanging elements arranged in the passage;

FIG. 5 is a plan view representing the positional relation between the heat-exchanging elements and the semiconductor package incorporated in the computer;

FIG. 6 is a sectional view of one of the heat-exchanging elements, which has its columnar part set in screw engagement with a base plate;

FIG. 7 is a sectional view of one of the heat-exchanging elements incorporated in a second embodiment of the invention;

FIG. 8 is a view of the heat-exchanging element, as seen in the direction of arrow X shown in FIG. 7;

FIG. 9 is a sectional view of one of the heat-exchanging elements provided in a third embodiment of the invention;

FIG. 10 is a sectional, exploded view of the heat-exchanging element shown in FIG. 9;

FIG. 11 is a sectional view of one of the heat-exchanging elements used in a fourth embodiment of this invention; and

FIG. 12 is a sectional view of one of the heat-exchanging elements incorporated in a fifth embodiment of this invention.

### DETAILED DESCRIPTION OF THE INVENTION

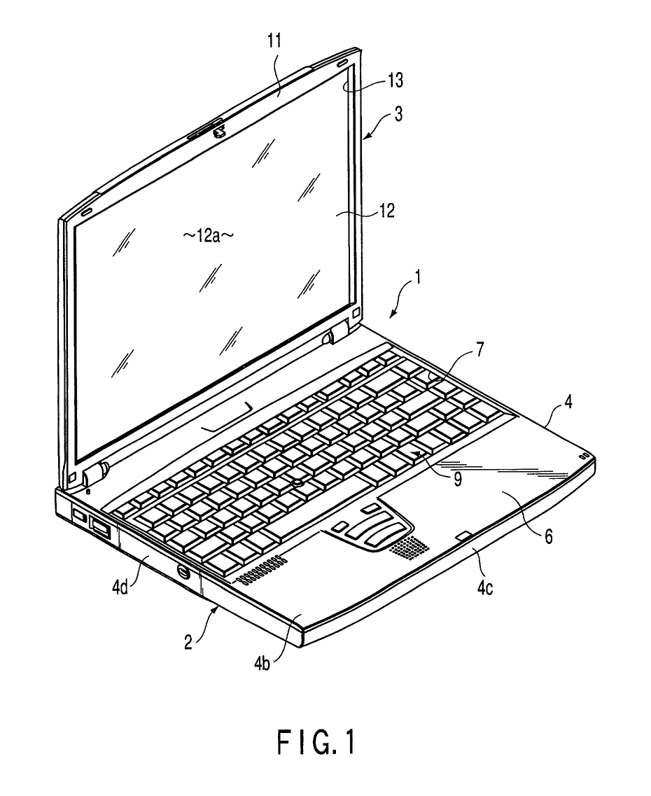

The first embodiment of the present invention, which is a portable computer, will be described with reference to FIGS. 1 to 6.

FIG. 1 shows the portable computer 1 that is a representative portable electronic apparatus. The portable computer 1 comprises a main body 2 and a display unit 3 supported on the main body 2.

The main body 2 comprises a housing 4 shaped like a flat box. The housing 4 has a bottom wall 4a, a top wall 4b, a front wall 4c, a pair of side walls 4d, and a rear wall 4e. The top wall 4b includes a palm rest 6 and a keyboard section 7. The palm rest 6 is provided on the front half of the housing 4. The keyboard section 7 is positioned at the rear of the palm rest 6. A keyboard 9 is set on the keyboard section 7. The rear wall 4e has an exhaust port 5.

The display unit 3 comprises a display housing 11 and a liquid crystal display (LCD) panel 12. Hinges (not shown) couple the display housing 11 to the rear end of the housing 4, enabling the display housing 11 to rotate. The display housing 11 contains the LCD panel 12. The LCD panel 12 has a display screen 12a. The display screen 12a is exposed through an opening 13 made in the front wall of the display housing 11.

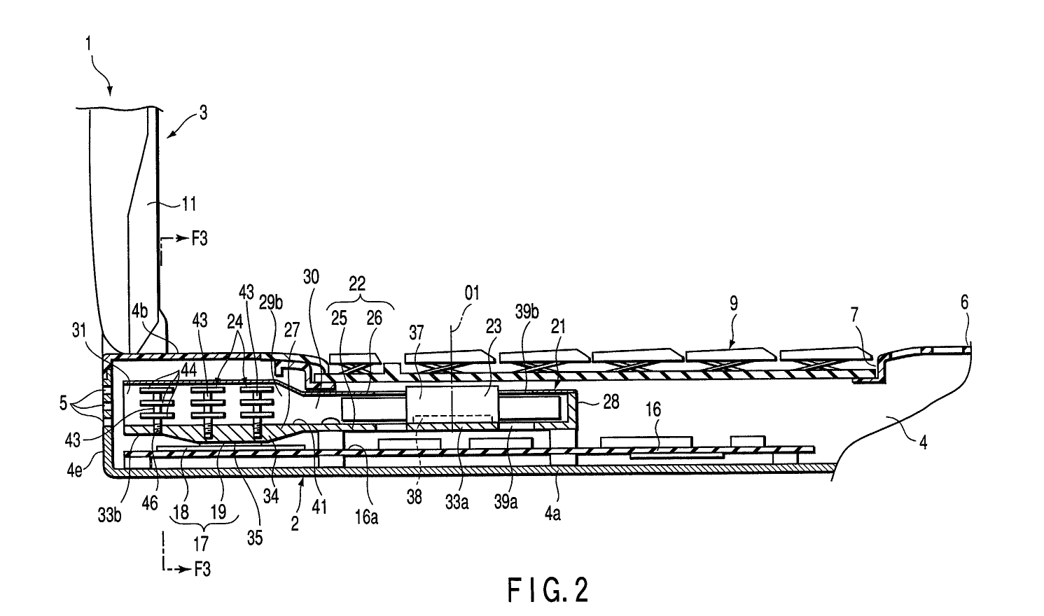

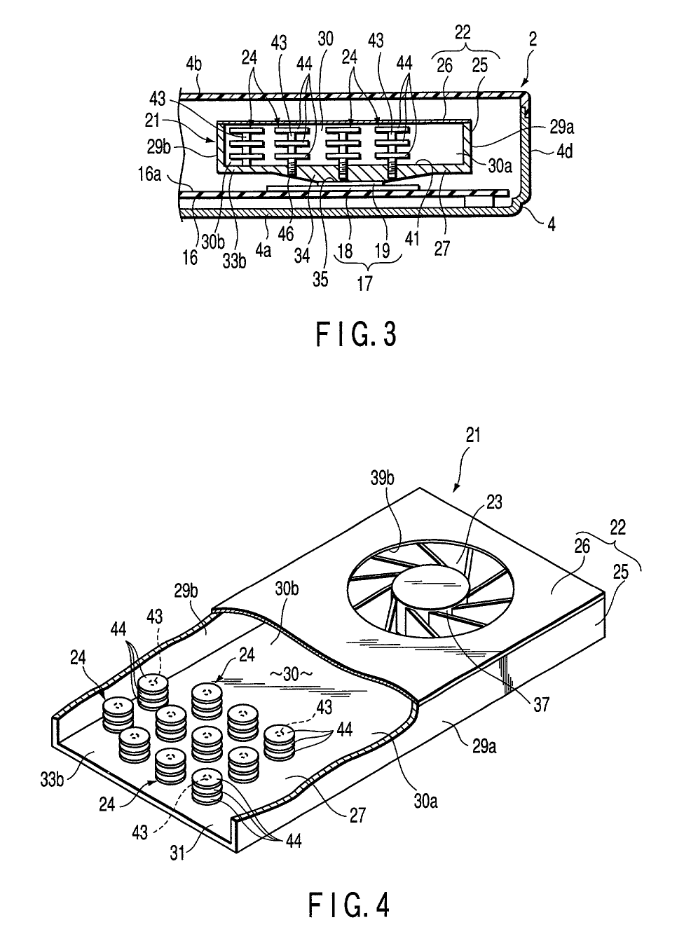

As FIGS. 2 and 3 show, the housing 4 contains a circuit board 16. The circuit board 16 lies below the keyboard 9 and extends parallel to the bottom wall 4a of the housing 4. The circuit board 16 has an upper surface 16a that opposes the top wall 4b and the keyboard 9. On the upper wall 16a there is mounted a semiconductor package 17, which is a heat-generating component.

The semiconductor package 17 is a microprocessor, i.e., the main component of the portable computer 1. The package 17 is arranged on the upper surface 16a of the circuit board 16, at the rear edge thereof. The package 17 comprises a base substrate 18 and an IC chip 19. The IC chip 19 is soldered to the base substrate 18. The chip 19 consumes much electric power because it processes multi-media data, such as characters, sound and images, at high speed. While operating, the IC chip 19 generates much heat while operating. It must be cooled in order to operate efficiently.

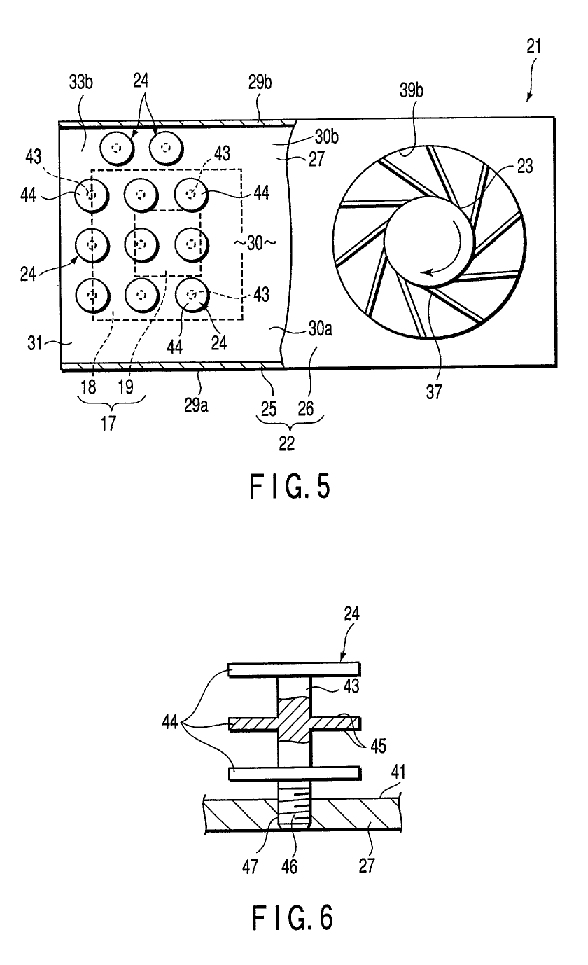

The housing 4 contains a cooling unit 21 that is configured to cool the semiconductor package 17 with air. As FIGS. 4 and 5 show, the cooling unit 21 comprises a main body 22, a fan 23, and a plurality of heat-exchanging elements 24. The main body 22, fan 23 and elements 24 are assembled together, constituting one module.

The main body 22 is made of a metal that excels in thermal conductivity, such as aluminum. It is a long flat box extending in the depth direction of the housing 4. The main body 22 comprises a base 25 and a top plate 26. The base 25 comprises a bottom plate 27, a front plate 28, and side plates 29a and 29b. The front plate 28 stand on the front edge of the bottom plate 27. The side plates 29a and 29b stand on the left and right edges of the bottom plate 27, respectively. The top plate 26 is laid on and secured to the upper edges of the front plate 28 and side plates 29a and 29b. It therefore opposes the bottom plate 27. The top plate 26 and the base 25 define a cooling air passage 30. The passage 30 extends in the depth direction of the housing 4. The cooling air passage 30 has an air outlet port 31 at the downstream end. The air outlet port 31 faces the exhaust port 5 of the housing 4.

As seen from FIGS. 2 and 3, the main body 22 is mounted on the circuit board 16. Its base 25 and the circuit board 16 are fastened to the bottom wall 4a of the housing 4 by means of screws.

The bottom plate 27 of the base 25 has a front half 33a and a rear half 33b. The rear half 33b is positioned right above the semiconductor package 17. The rear half 33b has a heat-receiving portion 34 that bulges downwards. The lower surface of the heat-receiving portion 34 functions as a heat-receiving surface 35. The heat-receiving surface 35 is thermally connected to the IC chip 19 by a heat-conducting sheet or heat-conducting grease. Hence, heat can be conducted from the IC chip 19 to the heat-receiving portion 34 and thence to the base 25. The heat can therefore be diffused to the main body 22.

The fan 23 is arranged at the upstream end of the cooling air passage 30. It has a centrifugal vane wheel 37 and a flat motor 38. The motor 38 drives the vane wheel 37. The vane wheel 37 and the motor 38 are supported on the front half 33a of the bottom plate 27 of the base 25. The vane wheel 37 lies in a horizontal position and between the top plate 26 and bottom plate 27 of the base 25, with its axis ° 1 extending in the vertical direction. The top plate 26 and the bottom plate 27 serve as a fan casing, as well. The plates 27 and 26 have inlet ports 39a and 39b for cooling air, respectively. The vane wheel 37 is automatically rotated around the axis O1 when the temperature of the semiconductor package 17 rises to a prescribed temperature.

When the fan 23 is driven, air is drawn toward the center of the vane wheel 23 through the inlet ports 39a and 39b. The air, or cooling air, flows from the circumference of the vane wheel 37 into the cooling air passage 30.

In the first embodiment, the vane wheel 37 is rotated clockwise as illustrated in FIG. 5. Hence, the vanes of the wheel 37 move toward the air outlet port 31 as they are seen from one side wall 29a of the base 25, and away from the air outlet port 31 as seen they are seen from the other side wall 29b of the base 25.

Most of the cooling air applied from the circumference of the vane wheel 37 therefore flows through a path extending along the side wall 29a, in the cooling air passage 30. In other words, more cooling air flows through this path, which shall be called “first air path 30a,” than through the path extending which extends along the side wall 29b and which shall be called “second air path 30b.” Thus, the cooling-air distribution is not uniform in the cooling air passage 30.

As shown in FIGS. 2 and 3, the bottom plate 27 of the base 25 has a flat guide surface 41 that opposes the cooling air passage 30. The guide surface 41 faces away from the heat-receiving surface 35 of the heat-receiving portion 34. The cooling air flows along the guide surface 41.

The heat-exchanging elements 24 are mounted on the guide surface 41. As shown in FIG. 6 that is a magnified view, each heat-exchanging element 24 has a columnar part 43 and a plurality of heat-radiating parts 44. The columnar part 43 and the heat-radiating parts 44 have been formed integral by casting and are made of metal such as copper-based alloy, which excels in thermal conductivity. The heat-exchanging elements 24 are not formed integral with the base 25 described above. The heat-radiating parts 44 are discs that have a larger diameter than the columnar part 43. They are arranged at intervals in the axial direction of the columnar part 43. The upper and lower surfaces of each heat-radiating part 44 have been processed to serve as main heat-radiating surfaces 45. The main heat-radiating surfaces 45 extend at right angles to the circumferential surface of the columnar part 43.

The columnar part 43 of each heat-exchanging element 24 has a screw 46 at one end. The screw 46 is set in a screw hole 47 cut in the rear half 33a of the bottom plate 27. Each heat-exchanging element 24 is thereby thermally connected to the bottom plate 27. Thus, the element 24 is removably fastened to the bottom plate 27 and protects from the guide surface 41 into the cooling air passage 30. That is, the element 24 is exposed to the cooling air passage 30, with its main heat-radiating surface 45 lying in parallel to the guide surface 41 of the bottom plate 27.

As seen from FIGS. 4 and 5, the heat-exchanging elements 24 are laid out in the form of a matrix, one spaced part from another. They are arranged in a limited area that lies right above the semiconductor package 17. More precisely, the heat-exchanging elements 24 are arranged in rows and columns. The rows of elements 24 extend parallel to the cooling air passage 30, whereas the columns of elements 24 extends at right angles to the direction in which the cooling air flows in the passage 30. The heat-radiating parts 44 of each element 24 are spaced from those of any other element 24.

Some of the heat-exchanging elements 24 lie in the first air path 30a of the passage 30, and the other heat-exchanging elements 24 lie in the second air path 30b of the passage 30. More elements 24 are provided in the second air path 30b than in the first air path 30a. This is because less cooling air flows through the second air path 30b than through the first air path 30a. Thus, the heat-exchanging elements 24 are arranged in higher density in the second air path 30b than in the first air path 30a.

The IC chip 19 of the semiconductor package 17 generates heat during the use of the portable computer 1. The heat is conducted to the heat-receiving portion 34 of the base 25. It is thence diffused to the main body 22 of the cooling unit 21.

The heat-exchanging elements 24 are arranged in rows and columns on that surface of the bottom plate 27 that faces away from the heat-receiving portion 34. The columnar parts 43 of the elements 24 are thermally coupled to the base plate 27. Therefore, most of the heat conducted from the heat-receiving portion 34 to the bottom plate 27 propagates from the columnar part 43 of each element 24 to the heat-radiating parts 44 thereof. The heat-radiating parts 44 have the main heat-radiating surface 45 each, which lie outside the circumferential surface of the columnar part 43. Hence, each heat-exchanging element 24 has a large heat-radiating area. Thus designed, the elements 24 can efficiently radiate the heat the semiconductor package 17 has generated.

When the temperature of the semiconductor package 17 rises to the prescribed value, the fan 23 is driven. The vane wheel 37 of the fan 23 rotates, drawing air through the inlet ports 39a and 39b and forcing the air into the cooling air passage 30. The air, i.e., cooling air, is applied onto the heat-exchanging elements 24 that are exposed in the cooling air passage 30. The cooling air passes the columnar parts 43 of the elements 24 and flows through the gaps between the main heat-radiating surfaces 45 of the heat-radiating parts 44. After passing the heat-exchanging elements 24, the cooling air is discharged from the air passage 30 through the air outlet port 31 and the exhaust port 5 of the housing 4.

In the cooling unit 21 described above, the cooling air flows through the cooling air passage 30 and cools the main body 22 and the heat-exchanging elements 24. Cooled with the cooling air, the main body 22 and the elements 24 efficiently radiate the heat generated by the semiconductor package 17 and conducted to the main body 22 from the heat-receiving portion 34. The cooling unit 21 can therefore maintain the semiconductor package 17 at a desirable thermal condition.

In the cooling unit 21, the heat-exchanging elements 24 are fastened to the bottom plate 27. That is, each heat-exchanging element 24 has lower end, i.e., the screw 46 of the columnar part 43, set in a screw hole 47 cut in the rear half 33a of the bottom plate 27. The heat-exchanging elements 24 are thereby thermally connected to the bottom plate 27. The elements 24 can be used in various numbers and can have their lower ends set in any selected ones of screw holes 47. In other words, any number of elements 24 can be arranged at any positions on the rear half 33a of the bottom plate 27, in accordance with the rate at which the cooling air flows through the cooling air passage 30 and the flow-rate distribution of air in the cooling air passage 30.

To be more specific, heat-exchanging elements 24 are arranged at high density in the second air path 30b, in which the cooling air flows at a low rate. The total heat-radiating area of the elements 24 is large in the second air passage 30b. The heat-exchanging efficiency is therefore high in the second air passage 30b. By contrast, heat-exchanging elements 24 are arranged at low density in the first air path 30a, in which the cooling air flows at a high. The resistance to the cooling air is therefore low in the first air path 30a. The cooling air can flow fast in the first air path 30a, enhancing the heat-exchanging efficiency.

Hence, the degree at which the elements 24 hamper the flow of cooling air can be adjusted in accordance with the flow rate of the cooling air and the flow-rate distribution thereof. An optimal cooling ability that the cooling unit 21 should have in view of the amount of heat generated by the semiconductor package 17 can be easily determined, not influenced by the rate at which the cooling air flows through the cooling air passage 30. The heat generated by the package 17 can therefore be radiated at a sufficiently high efficiency.

As described before, the heat-exchanging elements 24 are not formed integral with the base 25. The number of elements 24 used and the positions thereof can be changed freely, without the necessity of preparing various dies for forming the base 25. This helps reduce the manufacturing cost of the cooling unit 21 and ultimately contributes to a decrease in the price of the portable computer 1 that incorporates the cooling unit 21.

As indicated above, the heat-exchanging elements 24 that contact the cooling air are made of metal such as copper-based alloy, which is superior in thermal conductivity to the material of the base 25. This increases the efficiency of the heat exchange implemented as the elements 24 contact the cooling air. Thus, the material of the elements 24 serves to raise the efficiency of cooling the semiconductor package 17.

In the first embodiment, the heat-exchanging elements 24 are fastened to the base 25, with their lower ends set in the screw holes 47 made in the base 25. Nonetheless, the elements 24 may be fastened to the base 25 by other methods. For example, the columnar parts 43 of the elements 24 may be pressed into holes made in the base 25. Alternatively, the columnar parts 43 may be brazed, caulked, soldered, welded or adhered to the base 25.

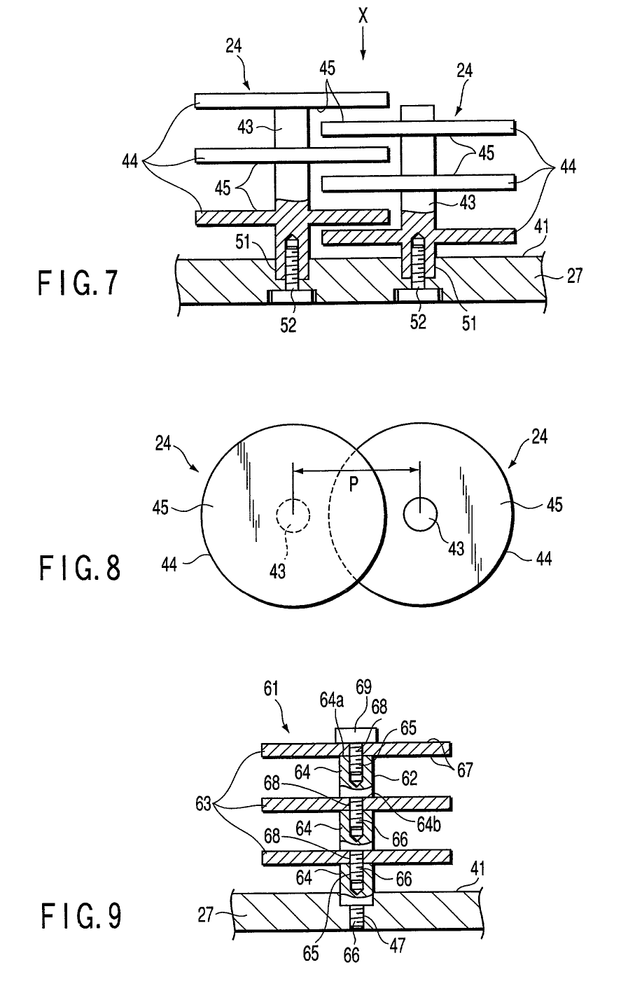

The present invention is not limited to the first embodiment described above. It may be applied to another embodiments, which will be described with reference to FIGS. 7 and 8.

In the second embodiment shown in FIGS. 7 and 8, the heat-radiating parts 44 of each heat-exchanging element 24 lie between those of any adjacent heat-exchanging element 24. Thus, the heat-radiating parts 44 of any adjacent elements 24 overlap in part (FIG. 8), as seen from the axial direction of the elements 24.

The bottom plate 27 of the base 25 has a plurality of recesses 51. The recesses 51 opens at the guide surface 41 and arranged in rows and columns in the guide surface 41. The columnar parts 43 of the elements 24 have their lower ends fitted in the recesses 51. The lower ends of the columnar parts 43 have screw holes. As shown in FIG. 7, screws 52 pass through the bottom plate 27 and are driven into the screw holes of the columnar parts 43, from the lower surface of the bottom plate 27, or the surface other than the guide surface 41. The heat-exchanging elements 24 are thereby fastened to the bottom plate 27.

Namely, each heat-exchanging element 24 is first fitted, at its lower end, into a recess 51 made in the bottom plate 27 and is then fastened to the plate 27 by means of a screw 52. Therefore, the elements 24 can be secured to the bottom plate 27, though the heat-radiating parts 44 of each element 24 overlap those of any adjacent element 24.

Any heat-exchanging elements 24 arranged adjacent to one another have their heat-radiating parts 44 interleaved with one another. The columnar parts 43 of the elements 24 can arranged in high density, shortening the distance P between them, as is illustrated in FIG. 8. Many heat-exchanging elements 24 can therefore be provided at high density in the cooling air passage 30. This enhances the freedom of adjusting the degree at which the elements 24 hamper the flow of cooling air in accordance with the flow rate of the cooling air. Moreover, this helps to render the main body 22 compact.

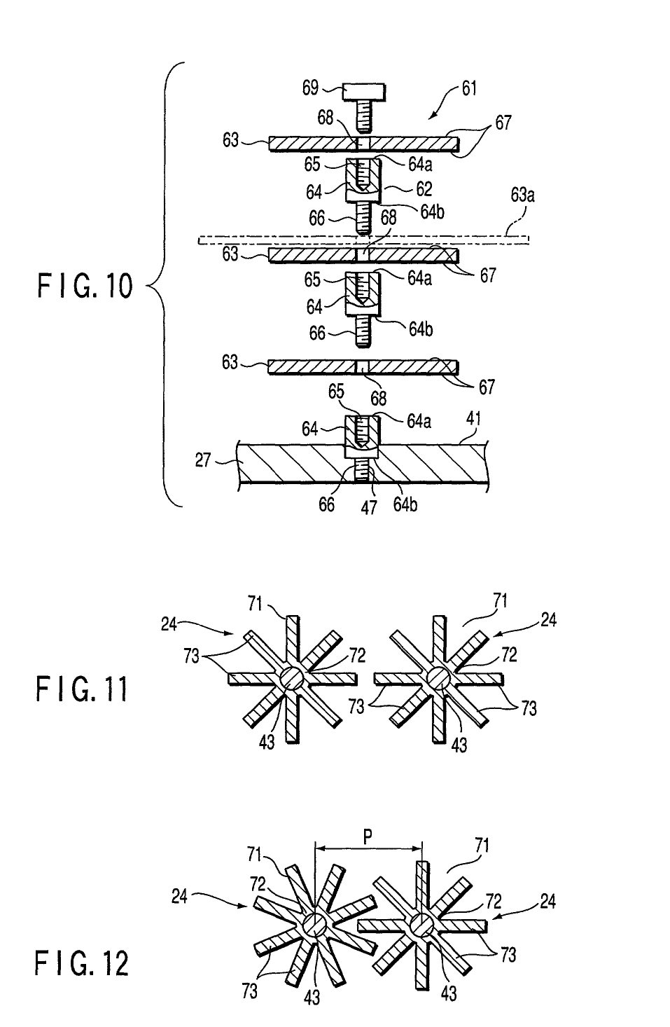

FIGS. 9 and 10 shows the third embodiment of the present invention.

The third embodiment differs from the first embodiment in the structure of the heat-exchanging elements 61 that are exposed in the cooling air passage 30.

As FIG. 9 shows, each heat-exchanging element 61 comprises a columnar part 62 and a plurality of heat-radiating parts 63. The heat-radiating parts 63 protrude from the circumferential surface of the columnar part 62. The columnar part 62 is composed of a plurality of cylinders 64. Each cylinder 64 has two ends 64a and 64b. Ends 64a and 64b have a flat surface each. The flat surface lies in a plane intersecting at right angles to the axis of the cylinder 64.

Each cylinder 64 has an axial screw hole 65 made in the first end 64a and a screw 66 protruding from the second end 64b in the axial direction. The screw 66 is driven into the screw hole 65 of another cylinder 64, whereby the cylinders 64 are fastened together in end-to-end relation, constituting the columnar part 62.

The heat-radiating parts 63 are discs that have a larger diameter than the columnar part 62. The upper and lower surfaces of each heat-radiating part 63 have been processed into flat main heat-radiating surfaces 67. Each heat-radiating part 63 has a through hole 68 in its center. The screw 66 protruding from the second end 64b of any cylinder 64 can pass through the hole 68.

Each heat-radiating part 63 is interposed between the first end 64a of one cylinder 64 and the second end 64b of an adjacent cylinder 64, so long as the screw 66 of the cylinder 64 passing through the hole 68 of the part 63 remains driven in the screw hole of the other cylinder 64. The columnar part 62 and the heat-radiating parts 63 are thereby fastened together, constituting a heat-exchanging element 61.

The uppermost heat-radiating part 63 is secured to the first end 64a of the uppermost cylinder 64 by means of a fastening screw 69 that is driven into the screw hole 65 made in the first end 64a of the uppermost cylinder 64.

In the third embodiment thus configured, the heat-radiating parts 63 can be removed from between the cylinders 64 constituting a columnar part 62 and interposed between the cylinders 64. The number of heat-radiating parts 63 of each heat-exchanging element 61 can therefore be changed. Additionally, the number of cylinders 64 forming each columnar part 62 can be changed, thereby to adjust the length of the columnar part 62.

Further, heat-radiating parts 63a of different diameters may be prepared, and the parts 63a of an optimal diameter may be selected and used as shown in FIG. 10, in accordance with the rate at which the cooling air flows through the cooling air passage 30.

These measures taken, each of the heat-exchanging elements 61 can have different shapes. This structural feature enables the cooling unit to acquire an optimal cooling ability that the unit should have in view of not only the flow rate of the cooling air in the passage 30, but also the amount of heat generated by the semiconductor package 17.

FIG. 11 illustrates the fourth embodiment of this invention.

The fourth embodiment differs from the first embodiment in the structure of the heat-radiating parts 71 of each heat-exchanging element 42.

As shown in FIG. 11, each heat-radiating part 71 has a boss 72 and a plurality of arms 73. The arms 73 project from the boss 72 in radial direction. The arms 73 are arranged at regular intervals in the circumferential direction of the columnar part 43. In the cooling air passage 30, the heat-radiating parts 71 of each heat-exchanging element 24 are spaced from those of any other heat-exchanging element 24.

In the fourth embodiment, each heat-radiating part 71 provided in the cooling air passage 30 has a plurality of arms 73 that extend in the radial direction. As the cooling air passes by the arms 73, it becomes turbulent. The resistance to the air therefore increases in the cooling air passage 30. Being turbulent, the cooling air contacts all arms 73 of each heat-radiating part 71. This helps enhance the efficiency of the heat exchanging each heat-exchanging element 24 performs.

FIG. 12 shows the fifth embodiment of the present invention. This embodiment is identical to the fourth embodiment, except that some of the arms 73 of each heat-radiating part 71 lie between some of the arms of any adjacent heat-radiating part 71.

In the fifth embodiment, the distance P between any adjacent heat-exchanging elements 24 can be shortened. This is because some of the arms 73 of each heat-radiating part 71 are interleaved with some of the arms of any adjacent heat-radiating part 71.

Hence, more heat-exchanging elements 24 can be arranged in the same unit area than in the fourth embodiment. That is, the elements 24 can be arranged in a higher density in the cooling air passage 30. It follows that the cooling air is rendered more turbulent as is desired.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A cooling unit for cooling a heat-generating component, comprising:
a main body which is thermally connected to the heat-generating component and having a cooling air passage;
a fan which applies cooling air into the cooling air passage; and
a plurality of heat-exchanging elements exposed in the cooling air passage and being thermally conductive, said heat-exchanging elements removably secured to the main body and thermally connected to the main body.

2. The cooling unit according to claim 1, wherein said each heat-exchanging element comprises a columnar part and at least one heat-radiating part projecting from a circumferential surface of the columnar part.

3. The cooling unit according to claim 2, wherein the columnar part of each heat-exchanging element is removably set in screw engagement with the main body.

4. The cooling unit according to claim 1, wherein the main body and each of the heat-exchanging elements are different in thermal conductivity.

5. The cooling unit according to claim 2, wherein the columnar part of each heat-exchanging element comprises a plurality of cylinders that are coupled coaxially and removably, and said at least one heat-radiating part is interposed between two adjacent cylinders.

6. The cooling unit according to claim 1, wherein the cooling air passage has a first air path and a second air path, the cooling air flows through the first air path at a higher rate than through the second air path, the heat-exchanging elements are arranged in the first and second air paths, and the number and positions of the heat-exchanging elements are changed in accordance a rate at which the cooling air flows through the air paths.

7. The cooling unit according to claim 1, wherein the main body has a guide surface opposing the cooling air passage, and the heat-exchanging elements project from the guide surface into the cooling air passage.

8. The cooling unit according to claim 7, wherein the main body has a heat-receiving surface which receives heat from the heat-generating component, and the guide surface is a side opposite to the heatreceiving surface.

9. The cooling unit according to claim 2, wherein said at least one heat-radiation part has a main heat-radiating surface which is flat and extends in a direction in which the cooling air flows.

10. The cooling unit according to claim 2, wherein said at least one heat-radiating part of each heat-exchanging element has a plurality of arms which project from circumferential surface of the columnar part, in radial direction thereof.

11. A cooling unit for cooling a heat-generating component, comprising:
a main body which is thermally connected to the heat-generating component and having a cooling air passage;
a fan which applies cooling air into the cooling air passage; and
a plurality of heat-exchanging elements exposed in the cooling air passage and being thermally conductive, each including a columnar part removably secured to the main body and thermally connected to the main body and including a plurality of heat-radiating parts projecting from a circumferential surface of the columnar part and arranged at intervals in an axial direction of the columnar part, and said heat-exchanging elements having such positional relation that the heat-radiating parts of each heat-exchanging element overlap the heat-radiating parts of some other heat-exchanging elements.

12. An electronic apparatus comprising:
a housing containing a heat-generating component; and
a cooling unit provided in the housing and configured to cool the heat-generating component, said cooling unit comprising:
a main body configured to receive heat from the heat-generating component;
a cooling air passage provided in the main body and configured to receive cooling air; and
a plurality of heat-exchanging elements exposed in the cooling air passage and being thermally conductive, said heat-exchanging elements removably secured to the main body and thermally connected to the main body.

13. The electronic apparatus according to claim 12, further comprising:
a circuit board provided in the housing and supporting the heat-generating component; and
a fan supported by the main body and configured to apply the cooling air into the cooling air passage.

14. The electronic apparatus according to claim 12, wherein said each heat-exchanging element comprises a columnar part and at least one heat-radiating part projecting from a circumferential surface of the columnar part.

15. The electronic apparatus according to claim 14, wherein the main body has a guide surface exposed in the cooling air passage, the columnar part of each heat-exchanging element is removably supported on the guide surface and projects from the guide surface into the cooling air passage.
